(19) United States
(12) Patent Application Publication
(10) Pub. No.: US 2024/0096733 A1
(43) Pub. Date: Mar. 21, 2024

(54) PACKAGE STRUCTURE AND METHOD FOR FABRICATING THE SAME

(71) Applicant: WISTRON NEWEB CORPORATION, HSINCHU (TW)

(72) Inventor: KUO-HUA HSIEH, HSINCHU (TW)

(21) Appl. No.: 18/323,484

(22) Filed: May 25, 2023

(30) Foreign Application Priority Data
Sep. 16, 2022 (TW) 111135017

(51) Int. Cl. H01L 23/367; H01L 21/48; H01L 23/498

(52) U.S. Cl. CPC H01L 23/3675; H01L 21/4871; H01L 23/3677; H01L 23/49816; H01L 23/49838

(57) ABSTRACT

A package structure and method for fabricating the same are provided. The package structure includes a substrate, a semiconductor package, a side dam, a flexible thermal conductor and a first heat sink. The substrate has a first board surface. The semiconductor package has an upper surface, a lower surface and a side surface, and the semiconductor package is disposed on the first board surface. The side dam is formed on the first board to surround a first accommodating space for accommodating the semiconductor package. The side dam has a height that is higher than a height of the upper surface. The flexible heat conductor is formed on the upper surface. The first heat sink is disposed on the side dam. The first heat sink, the side dam and the semiconductor package jointly define a second accommodation space to confine the flexible heat conductor.

### CROSS-REFERENCE TO RELATED PATENT APPLICATION

This application claims the benefit of priority to Taiwan Patent Application No. 111135017, filed on Sep. 16, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure and a method for fabricating the same, and more particularly to a package structure and a method for fabricating the same that can effectively improve product reliability.

### BACKGROUND OF THE DISCLOSURE

Liquid thermal interface materials (LTIM) include heat dissipation glue, heat dissipation paste, liquid metal, and the like, which are commonly used between a heatsink and a chip or between a package component and a lid. Heat conductive materials for the LTIM can include metals, metal oxides, silicon dioxide, or ceramic microspheres.

Since highly thermal conductive liquid materials or liquid metals are electrically conductive, in a chip package process using underfill dispensing, foam frames or adhesive frames need to be additionally attached around the chip to form a barrier, so as to avoid leakage of liquid thermal interface material which can cause short circuits or damage to other components around the chip package. Therefore, in terms of overall process cost, in addition to time costs of processes such as cleaning, baking, surface treatment, and waiting for the underfill adhesive to infiltrate a underneath of the chip during the underfill process, there are additional material and process costs involved due to the need for setting up a gel frame or foam frame to prevent the liquid thermal interface materials from affecting the surrounding circuit or component soldering points.

In addition, liquid heat dissipation grease or liquid metal may leak due to package component warpage caused by product drop, vibration, or other mechanical or thermal stresses, which can result in insufficient amount of the liquid thermal interface material between the chip package and the heatsink or the lid. Such insufficient amount may affect heat dissipation efficiency and cause the chip or package component operate at excessively high temperatures, which can affect product reliability or cause the chip or packaged component to be burnt out.

Therefore, ensuring that liquid heat dissipation grease does not leak and remains in or is confined to a designated area during reflow or reliability tests, has become one of the important issues to be addressed in the art.

### SUMMARY OF THE DISCLOSURE

In response to the above-referenced technical inadequacies, the present disclosure provides a package structure and a method for fabricating the same that can effectively improve product reliability.

In one aspect, the present disclosure provides a package structure, which includes a substrate, a semiconductor package, a side dam, a flexible heat conductor and a first heat sink. The substrate has a first board surface and a second board surface. The semiconductor package has an upper surface, a lower surface, and a side surface between the upper surface and the lower surface. The semiconductor package is disposed on the first board surface, and is electrically connected to the substrate through a plurality of pins disposed on the lower surface. The side dam is formed on the first board to surroundingly define a first accommodating space. The semiconductor package is disposed in the first accommodating space and contacts the side dam, and the side dam has a height that is higher than a height of the upper surface. The flexible heat conductor is disposed on the upper surface. The first heat sink is disposed on the side dam and the flexible heat conductor, and is supported by the side dam. The first heat sink, the side dam and the semiconductor package jointly define a second accommodating space, and the flexible heat conductor is confined in the second accommodating space.

In another aspect, the present disclosure provides a method for fabricating a package structure, and the method includes: providing a substrate having a first board surface and a second board surface; disposing a semiconductor package on the first board, and electrically connecting the semiconductor package to the substrate through a plurality of pins, in which the semiconductor package has an upper surface, a lower surface, and a side surface between the upper surface and the lower surface, a first vertical projection is formed by projecting the semiconductor package onto the first board surface, and the plurality pins are disposed on the lower surface; performing a dispensing process to form a side dam contacting the semiconductor package on the first board surface to surroundingly define a first accommodating space for accommodating the semiconductor package, in which a height of the side dam is higher than a height of the upper surface; disposing a flexible heat conductor on the upper surface; and disposing a first heat sink on the side dam and the flexible heat conductor, in which the first heat sink is supported by the side dam, and the first heat sink, the side dam and the semiconductor package jointly define a second accommodating space, and the flexible heat conductor is confined in the second accommodating space.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for fabricating a package structure according to one embodiment of the present disclosure;

FIG. 2 is a schematic top view of a substrate according to one embodiment of the present disclosure;

FIG. 3 is a schematic side view of a substrate, a semiconductor package and a first adhesive according to one embodiment of the present disclosure;

FIGS. 4A to 4D are a first schematic top view and first to third side views depicting a dispensing process in step S104 according to one embodiment of the present disclosure;

FIGS. 5A to 5C are a second schematic top view and fourth and fifth schematic side views depicting the dispensing process in step S104 according to one embodiment of the present disclosure;

FIG. 6 is a schematic side view depicting a disposing process in step S106 according to one embodiment of the present disclosure;

FIG. 7 is a schematic side view depicting a disposing process in step S108 according to one embodiment of the present disclosure;

FIG. 8 is a schematic side view of another aspect of the package structure provided by the present disclosure;

FIG. 9 is a schematic side view of yet another aspect of the package structure provided by the present disclosure;

FIG. 10 shows a schematic top view of one implementation of the side dam according to one embodiment of the present disclosure;

FIGS. 11A and 11B respectively show a schematic top view and a schematic side view of another implementation of the side dam according to one embodiment of the present disclosure;

FIG. 12 shows a schematic top view of another implementation of the side dam according to one embodiment of the present disclosure;

FIGS. 13A and 13B are schematic top views of yet another implementation of the side dam according to one embodiment of the present disclosure; and

FIG. 13C is a schematic cross-sectional view taken along line I-I of FIG. 13B.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

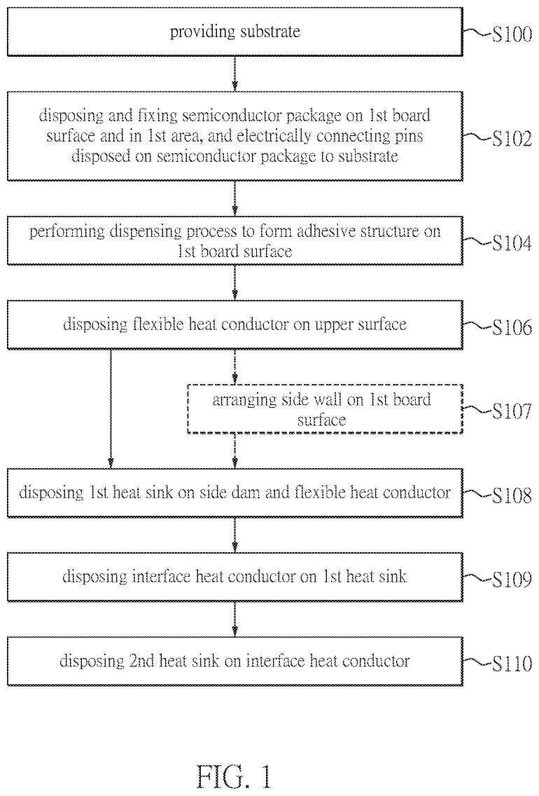

FIG. 1 is a flowchart of a method for fabricating a package structure according to one embodiment of the present disclosure. Referring to FIG. 1, one embodiment of the present disclosure provides a method for fabricating a package structure, and the method includes the following steps:

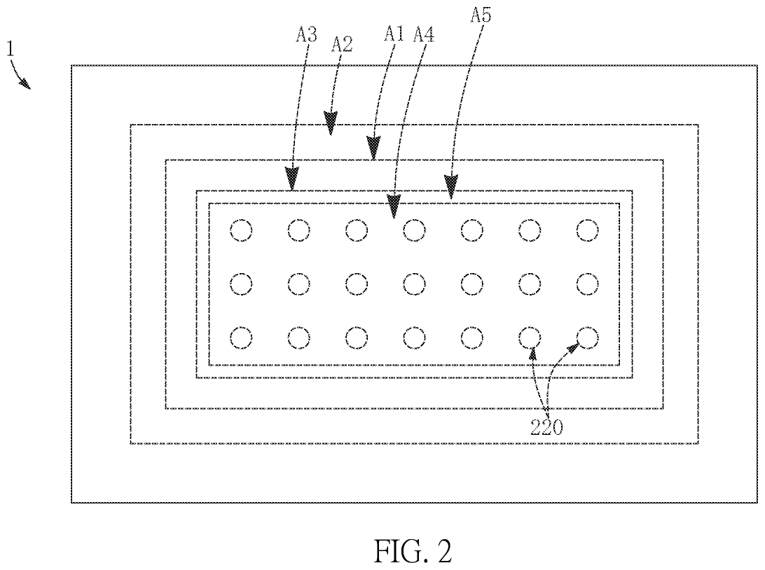

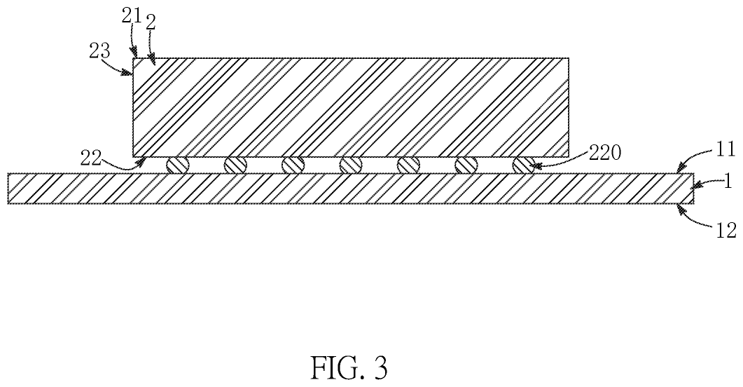

Step S100: providing a substrate. Reference can be made to FIGS. 2 and 3, where FIG. 2 is a schematic top view of a substrate according to one embodiment of the present disclosure, and FIG. 3 is a schematic side view of a substrate, a semiconductor package and a first adhesive according to one embodiment of the present disclosure. As shown in FIGS. 2 and 3, the substrate 1 has a first board surface 11 and a second board surface 12, and a first area A1 is located on the first board surface 11, and the second area A2 surrounds the first area A1.

Step S102: disposing and fixing the semiconductor package on the first board surface and in the first area, and electrically connecting a plurality of pins disposed on the semiconductor package to the substrate.

As shown in FIG. 3, the semiconductor package 2 can be an integrated circuit (IC) chip, which is a chip that integrates hundreds to millions or more components together. The semiconductor package 2 has an upper surface 21, a lower surface 22 located opposite to the upper surface 21, and a side surface 23 between the upper surface 21 and the lower surface 22. The pins 220 are disposed on the lower surface 22 and can be packaged in a grid pattern arrangement to fully cover the lower surface 22. During operation, electronic signals can be sent from the integrated circuits to a printed circuit board (PCB) where the pins are located on. It should be noted that, referring to FIG. 2, the lower surface 22 is divided into an inner area A4 and an outer area A5 surrounding the inner area A4. These pins 220 are disposed in the inner area A4, and the inner area A4 and the outer area A5 are shown in forms of dashed boxes in FIG. 2.

In FIG. 2, the semiconductor package 2 is disposed on the first board surface 11 of the substrate 1, and is located in the first area A1. More precisely, the semiconductor package 2 can be disposed in a pre-planned third area A3 on the first board surface 11. The third area A3 is a first vertical projection of the semiconductor package 2 formed onto the first board surface 11. In addition, the semiconductor package body 2 can be bonded to the substrate 1 using a flip-chip (FC), wafer level package (WLP) or quad flat no-lead (QFN/dual flat no-lead (DFN) form, such that the semiconductor package 2 is electrically connected to the substrate 1 through the pins 220, and the pins 220 can be connected to the semiconductor package 2 and the substrate 1 by welding. For example, the pins 220 are electrically connected to the substrate through a ball grid array (BGA) package method, that is, multiple solder balls are formed on the lower surface 22 in an array to form spherical contacts as the pins 220.

Step S104: performing a dispensing process to form an adhesive structure on the first board surface.

In detail, the purpose of step S104 is to form a side dam filling structure, which can effectively confine a liquid thermal interface material to an area above the semiconductor package 2 and also protect the semiconductor package 2. For this purpose, in one embodiment of the present disclosure, an adhesive with specific characteristics can be selected and a stacking-dispensing method or a bridge dispensing method can be used to repeatedly add the adhesive at the same location, so as to control the increase in fillet width and control the fillet height until a desired height is reached in a limited dispensing area, thereby forming a barrier to block the liquid thermal interface material.

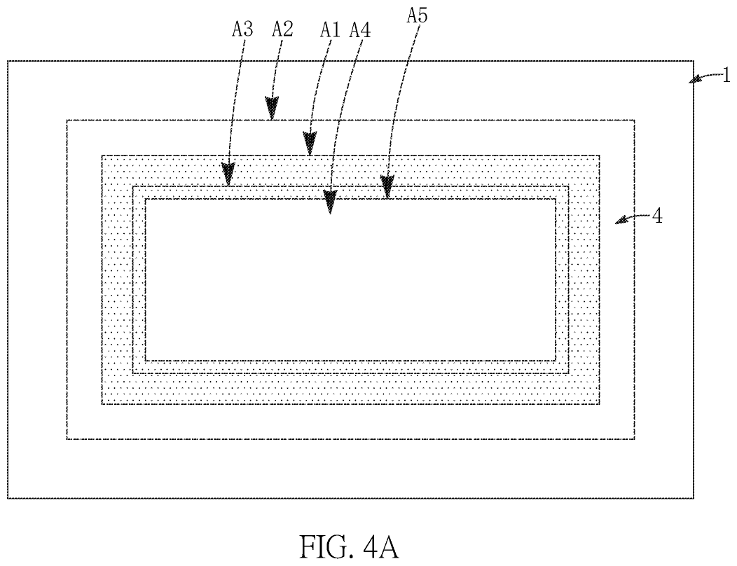

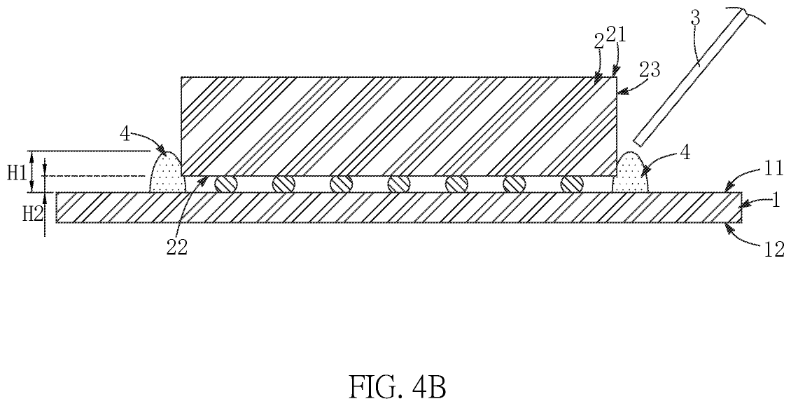

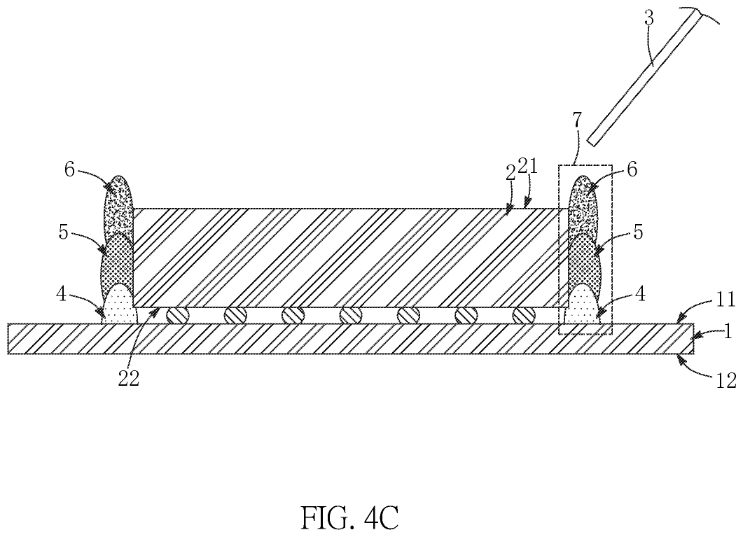

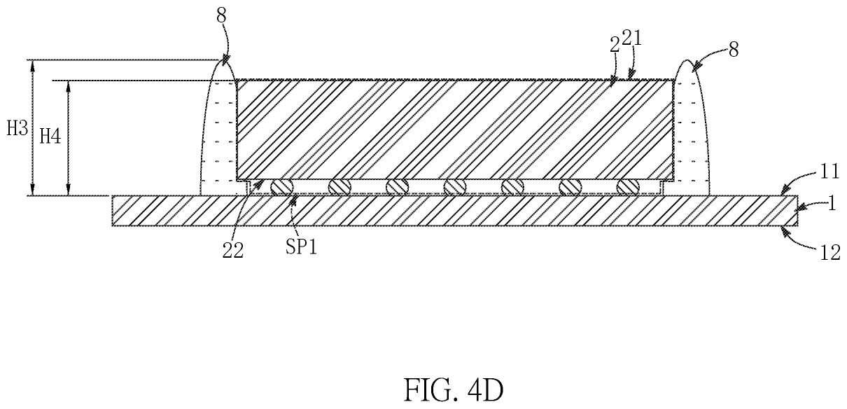

First, the stacking-dispensing method will be described. Reference is made to FIGS. 4A to 4D, which are a first schematic top view and first to third side views depicting a dispensing process in step S104 according to one embodiment of the present disclosure. As shown in FIGS. 4A and 4B, the first adhesive 4, the second adhesive 5 and the third adhesive 6 can be applied through multiple dispensing steps along at least a part among the side surface 23 of the semiconductor package 2 and a periphery of the third area A3 on the first board surface 11 through a syringe 3. For example, the first adhesive 4, the second adhesive 5 and the third adhesive 6 can be applied in the first area A1 shown in FIG. 4A, and in a part of the third area A3 adjacent to the first area A1.

In general, during the package process, the reliability of solder ball joints is ensured through dispensing processes such as underfill dispensing or side-fill dispensing. Viscosity, temperature, height and pressure of fluid in the needle cylinder, inner diameter and length of a needle tip, amount and shape of the dispensing can be controlled by a dispenser to determine a morphology of the formed adhesive.

From the top view in FIG. 4A, in the embodiment of the present disclosure, an amount of the first adhesive 4 is dispensed in a small amount to ensure a fillet width, so as not to penetrate or slightly penetrate a bottom of the semiconductor package 2 before a fillet shape is formed. In one preferred embodiment, the fillet width formed by the first adhesive 4 is less than or equal to 0.7 mm. For example, the first adhesive 4 may or may not be in contact with the side surface 23 of the semiconductor package 2 in an initial state, and subsequently may contact a part of the side surface 23 and a part of the lower surface 22 at the same time after the shape is stabilized. For example, the first adhesive 4 can contact the outer area A5 of the lower surface 22, but the present disclosure is not limited thereto. It should be noted that a height H1 of the first adhesive 4 in the initial state or in the stable state is at least higher than a height H2 of the lower surface 22.

It should be further noted that, in the embodiment where spherical contacts (the pins 220) are formed on the lower surface 22 in an array using multiple solder balls, the first adhesive 4 does not contact any of the pins 220 in the initial state or after the shape becomes stable. However, in the embodiment where the pins 220 are not formed in the BGA form, such as in a dual in-line package or quad flat non-leaded package (QFN) package, the first adhesive 4 may contact the side surface 23 and the bottom surface 22, as well as the outermost pin 220, but it is necessary to ensure that the adhesive does not completely cover the contacted lead 220.

In addition, in one embodiment of the present disclosure, adhesive materials with specific characteristics are also selected, and reference is made to the following Table I:

TABLE I

| Adhesive characteristics | Recommended range |
|---|---|
| Viscosity 25° C. (Pa · s) | ≥60 |
| Thixotropy | ≥3 |
| Glass transition temperature Tg (° C.) | ≥120 |
| Coefficient of thermal expansion (CTE) | ≤120 |
| Modulus (Modulus) 25° C. (Gpa) | 6~10 |

Referring to FIG. 4C, the second adhesive 5 and the third adhesive 6 may be placed on the same horizontal position above the first adhesive 4 shown in FIG. 4B until the required adhesive height is reached, a multilayer structure 7 is then formed. It should be noted that an adhesive height of the multilayer structure 7 needs to be higher than a sum of a total height of the semiconductor package 2 and a height of a flexible heat conductor to be disposed, and a required amount and dispensing times of the adhesive depend on the adhesive height.

Next, as shown in FIG. 4D, after the multilayer structure 7 is solidified and molded, a side dam 8 that contacts the semiconductor package 2 can be formed, which forms to surroundingly define a first accommodating space SP1 for accommodating the semiconductor package 2, and a height H3 of the side dam 8 is higher than a height H4 of the upper surface S21. It should be noted that the first adhesive 4, the second adhesive 5, and the third adhesive 6 can use adhesives with the same or similar adhesive properties as those listed above. Therefore, in some embodiments, the side dam 8 may have a relatively apparent layered form, which can be seen to be formed by multiple layers of the adhesive, or may not have an obvious layered form.

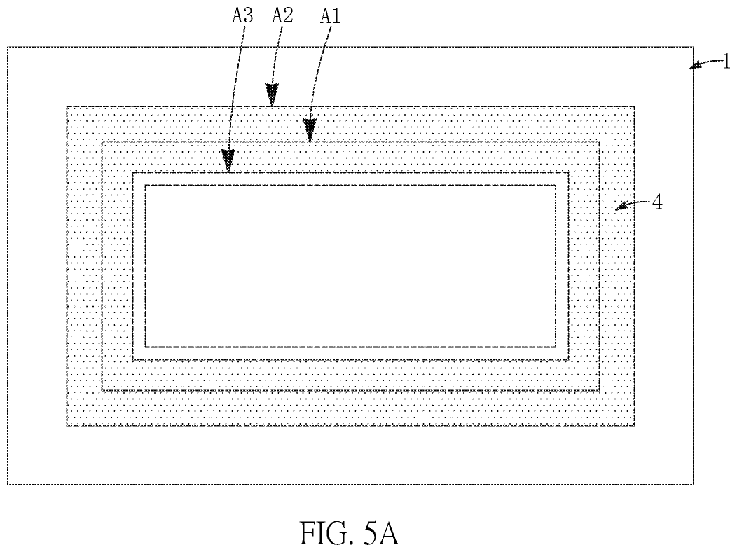

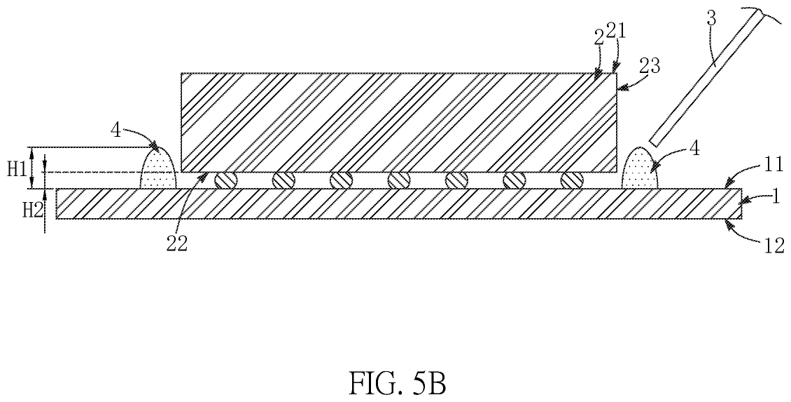

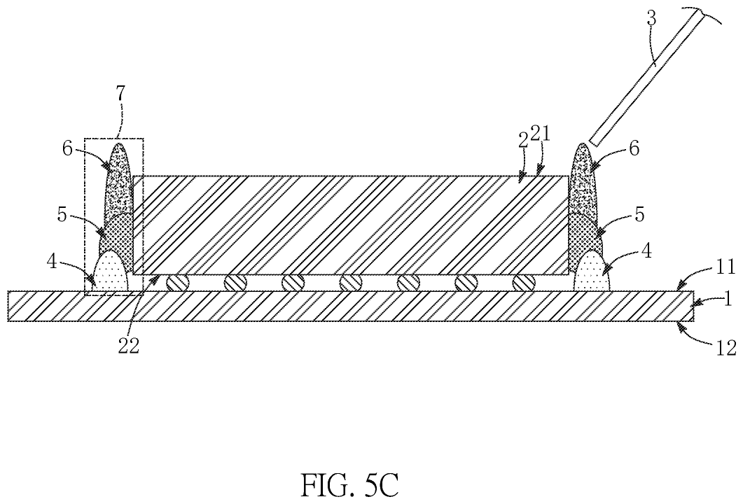

Next, the bridge dispensing method will be described. Reference is made to FIGS. 5A to 5C, which are a second schematic top view and fourth and fifth schematic side views depicting the dispensing process in step S104 according to one embodiment of the present disclosure. As shown in FIG. 5A, FIG. 5B and FIG. 5C, the first adhesive 4 can be applied on the first board surface 11 through the syringe 3 along at least a part among the side surface 23 of the semiconductor package 2 and the periphery of the third area A3. For example, the first adhesive 4 can be applied in the second area A1 as shown in FIG. 5A, and in a part of the second area A4 adjacent to the first area A1.

From the top view in FIG. 5A, in the embodiment of the present disclosure, an amount of the first adhesive 4 is dispensed in a small amount to ensure a fillet width, so as not to even slightly penetrate a bottom of the semiconductor package 2 before a fillet shape is formed. In one preferred embodiment, the fillet width formed by the first adhesive 4 is less than or equal to 0.7 mm. In FIG. 5A, the first adhesive 4 does not contact the side surface 23 of the semiconductor package 2 in an initial state, and subsequently may contact a part of the side surface 23 and a part of the lower surface 22 at the same time after the shape is stabilized. For example, the first adhesive 4 can contact the outer area A5 of the lower surface 22, but the present disclosure is not limited thereto. It should be noted that a height H1 of the first adhesive 4 in the initial state or in the stable state is at least higher than a height H2 of the lower surface 22.

Referring to FIG. 5C, the second adhesive 5 and the third adhesive 6 may be placed on positions above the first adhesive 4 shown in FIG. 5B, and especially, the positions between the first colloid 4 and the side surface 23 until the required adhesive height is reached, a pier-liked multilayer structure 7 is then formed. It should be noted that the second adhesive 5 is positioned closer to the side surface 23 than the first adhesive 4, and the third adhesive 6 can be positioned closer to the side surface 23 than the second adhesive 5, or at the same level as the second adhesive layer 5. An adhesive height of the multilayer structure 7 needs to be higher than a sum of a total height of the semiconductor package 2 and a height of a flexible heat conductor to be disposed, and a required amount and dispensing times of the adhesive depend on the adhesive height. Similarly, as shown in FIG. 5C, after the pier-like multilayer structure 7 is solidified and molded, the side dam 8 contacting the semiconductor package 2 can be formed.

Therefore, in step S104, multiple layers of adhesive can be sequentially stacked along at least a part among the side surface 23 and the periphery of the first vertical projection (i.e., the third area A3) by performing multiple dispensing steps, and the side dam 8 is formed after a shape of the multilayer adhesive structure is completely formed.

Step S106: disposing a flexible heat conductor on the upper surface.

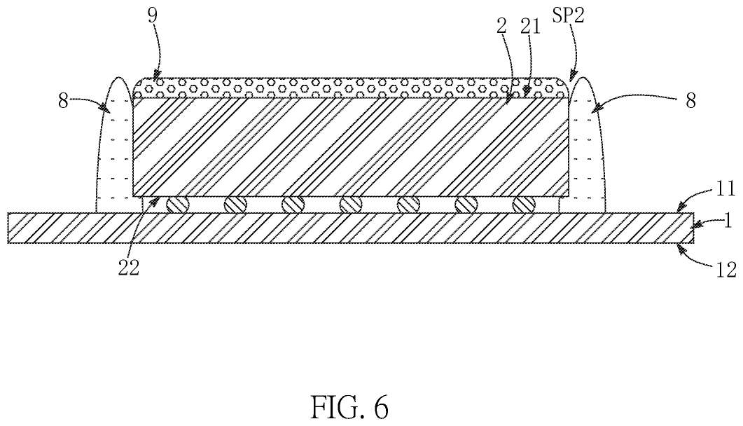

Reference is made to FIG. 6, which is a schematic side view depicting a disposing process in step S106 according to one embodiment of the present disclosure. As shown in FIG. 6, since the flexible heat conductor 9 usually has properties of glue, it can be disposed on the upper surface 21 of the semiconductor package 2 through a dispensing process similar to the previous steps. In this embodiment, the flexible heat conductor is made of a heat-conducting material, and the heat-conducting material can be, for example, a liquid metal, a metal alloy, a thermal grease, or a thermal adhesive with high thermal conductivity. In addition, it should be noted that a height of the flexible heat conductor 9 must be less than or equal to the height of the side dam 8. In addition, the aforementioned heat-conducting material can also include metals, metal oxides, silicon dioxide, or ceramic microspheres, and has advantages such as no stratification, no cracking, less bubbles, low thermal expansion coefficient, and high thermal conductivity.

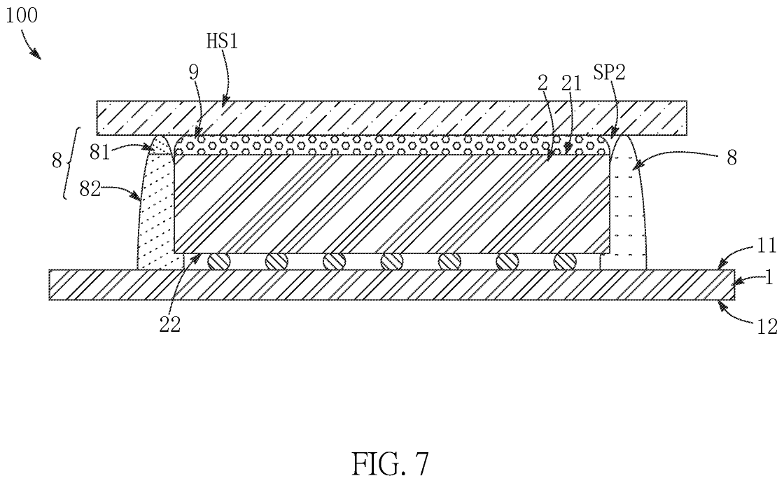

Step S108: disposing a first heat sink on the side dam and the flexible heat conductor. Reference is made to FIG. 7, which is a schematic side view depicting a disposing process in step S108 according to one embodiment of the present disclosure. In this step, the first heat sink HS1 is supported by the side dam 8, and the first heat sink HS1, the side dam 8 and the semiconductor package 2 jointly define a second accommodation space SP2, and the flexible heat conductor 9 is confined in the second accommodating space SP2. In addition, the first heat sink HS1 can be fixed above the side dam 8 by adhesive, and the two can be bonded together by an encapsulant such as epoxy resin. Alternatively, the first heat sink HS1 can also be fixed by the adhesive capability provided by the flexible heat conductor 9 itself.

For example, the first heat sink HS1 can be a metal plate that can be used for heat dissipation, or a metal plate with a specific structure, such as a fin radiator, which can be made of metal with high thermal conductivity, but the present disclosure is not limited thereto.

After step S108 is performed, one aspect of the package structure 100 provided by the present disclosure is completed. Therefore, the side dam filling structure and the related method for fabricating the same used in the present disclosure, combined with adhesives having properties such as high viscosity, low coefficient of thermal expansion, and high thixotropic index, stress resistance of the semiconductor package 2 can be strengthened, and a blocking wall structure above the semiconductor package 2 can be provided as a region-limited barrier for the flexible heat conductor 9 without additional adhesive frames. Therefore, the deformation (warpage) of the semiconductor package 2 caused by mechanical or thermal stress can be reduced, and the leakage of liquid heat dissipation grease can be avoided, which affects the heat dissipation requirements of the product, thereby improving reliability and reducing cost.

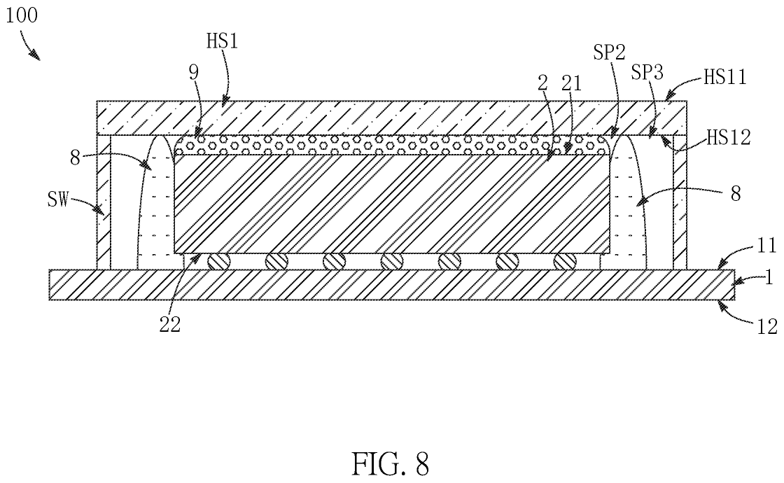

Optionally, before step S108 is performed, step S107 can be further performed first: arranging a side wall on the first board surface. Therefore, reference is made to FIG. 8, which is a schematic side view of another aspect of the package structure provided by the present disclosure. As shown in FIG. 8, the first heat sink HS1 has a first surface HS11 and a second surface HS12, the second surface HS12 contacts the side dam 8, and the side wall SW can be located between the first board surface 11 and the second surface HS12 of the first heat sink HS1, so as to jointly form a package cover with the first heat sink HS1 that defines a third accommodating space SP3 for accommodating the semiconductor package 2, the side dam 8 and the flexible heat conductor 9. It should be noted that the side wall SW can be used to support the first heat sink HS1, or be integrally formed with the first heat sink HS1. Therefore, the side wall SW can be provided with the same or similar material as that of the first heat sink HS1, and the present disclosure is not limited thereto. It should be noted that a second vertical projection is formed by projecting the side dam 8 onto the second surface HS12, and an area of the second surface HS12 is larger than an area formed by a periphery of the second vertical projection. That is, from the top view, the first heat sink HS1 completely covers the side dam 8.

It should be noted that, in the embodiments shown in FIGS. 7 and 8, the side dam 8 can contact a part of the lower surface 22 and a part or all of the side surface 23. When the side dam 8 only contacts a part of the side surface 23, a flow space can be reserved for the flexible heat conductor 9 on the side surface 23, and can provide lateral thermal paths for the semiconductor package 2 when the flexible heat conductor 9 contacts the side surface 23. In addition, in order to enhance a structural strength of the side dam 8, the side dam 8 essentially has a dam cross section that is wider at a bottom and narrower at a top.

Optionally, as shown in FIG. 1, in the method provided by the present disclosure, the following steps are also included:

Step S109: disposing an interface heat conductor on the first heat sink.

Step S110: disposing a second heat sink on the interface heat conductor.

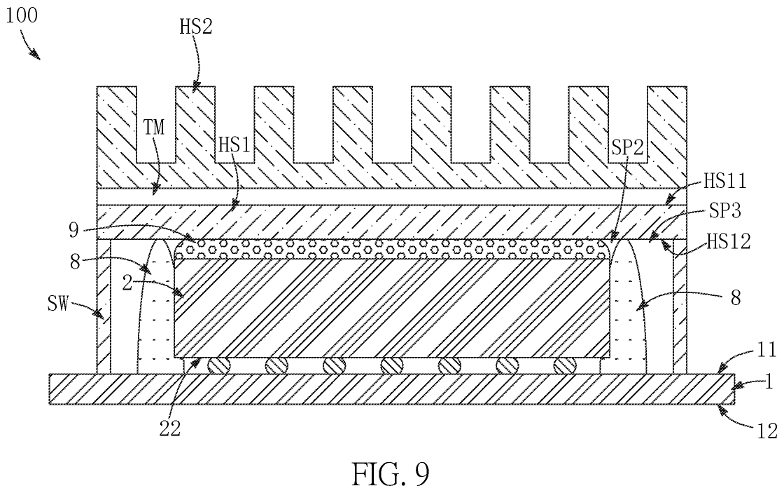

Reference is made to FIG. 9, which is a schematic side view of yet another aspect of the package structure provided by the present disclosure. In step S109, a thermal interface conductor TM can be, for example, a thermal interface material (TIM), which is a material used for coating between a heat dissipation device and a heat generation device to reduce contact thermal resistance. The interface thermal conductor TM can be made of materials such as thermal grease, thermal pad, thermal conductive adhesive, and the like. On the other hand, in step S110, the second heat sink HS2 can be a metal plate that can be used for heat dissipation, or a metal plate with a specific structure, such as a fin radiator, which can be made of metal with high thermal conductivity, but the present disclosure is not limited thereto. Moreover, through a configuration that combines the interface heat conductor TM and the second heat sink HS2, a heat dissipation efficiency of the package structure can be further improved.

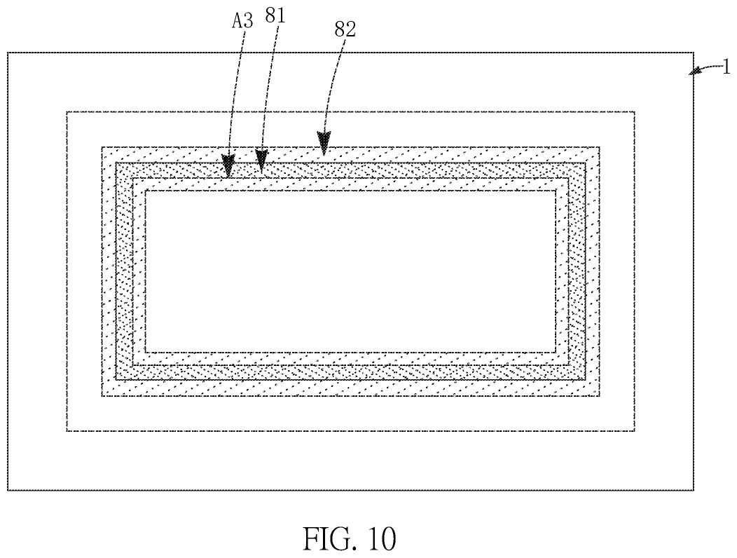

Reference is made to FIG. 10, which shows a schematic top view of one implementation of the side dam according to one embodiment of the present disclosure. Reference is also made to FIG. 7, in which the side dam 8 can include an upper dam 81 that is higher than the upper surface 21 and a lower dam 82 lower than the upper surface 21. In this case, the upper dam 81 represents a portion raised from the side dam 8 to serve as the blocking wall for the flexible heat conductor 9 in the previous embodiment, and the lower dam 82 represents a dispensing part that contacts the side surface 21.

As shown in FIG. 10, a vertical projection of the semiconductor package 2 is a third area A3, which can be, for example, a rectangle. In some embodiments, if the finished product of the package structure provided by the present disclosure does not need to be reflowed again for one or more times, since a gas expansion effect during sealing does not need to be considered, there is no need to leave any opening in the upper dam 81 and the lower dam 82. Therefore, the upper dam 81 and the lower dam 82 corresponding to each edge of the rectangle are completely covered.

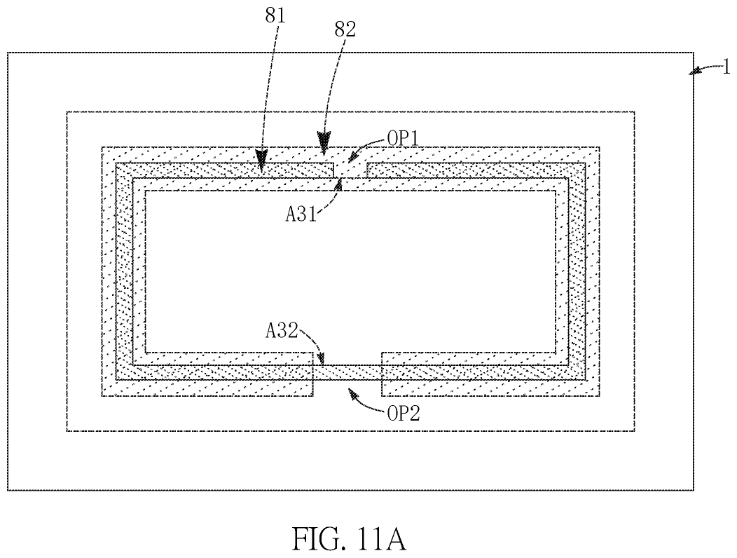

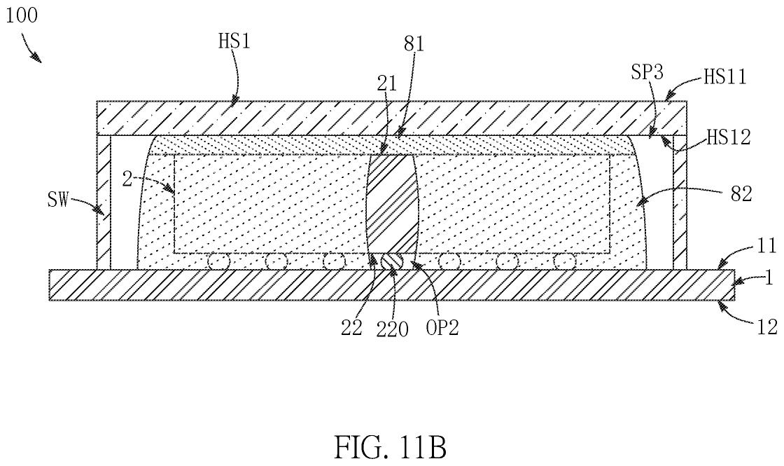

Reference is made to FIGS. 11A and 11B, which respectively show a schematic top view and a schematic side view of another implementation of the side dam according to one embodiment of the present disclosure. As shown in FIG. 11A, if the finished product of the package structure provided by the present disclosure needs to be reflowed again for one or more times, the gas expansion effect during sealing needs to be considered, and the upper dam 81 and the lower dam 82 need to be kept open. In the present embodiment, in a part of the side dam 8 corresponding to a first edge A31 of the rectangle, the upper dam 81 has a first opening OP1, and in a part of the side dam 8 corresponding to a second edge A32 of the rectangle, the lower dam 82 has a second opening OP2, and the first edge A31 is located opposite to the second edge A32.

Further reference can be made to FIG. 11B, which shows an arrangement of the second opening OP2 in FIG. 11A from another perspective. As shown in FIG. 11B, in the process of forming the second opening OP2, the lower dams 82 on both sides of the second opening OP2 can be stacked with the adhesives until reaching the upper surface 21, and then the lower dams 82 on both sides of the second opening OP2 are used as bases, so as to gradually stack the upper dam 81 above the second opening OP2 in a direction starting from both sides toward a center, and finally forming a shape similar to an arch. The formed second opening OP2 can be an escape path preserved for gas below the semiconductor package 2. However, a manner of forming the second opening OP2 is not limited thereto. In other embodiments, adhesives can also be dispensed on the upper surface 21 of the semiconductor package 2 near the side dam 8 to form the upper dam 81 above the second opening OP2.

Therefore, in the reflow process, the second opening OP2 can provide an escape path for gas at the bottom of the semiconductor package 2, and will not cause the gas to have nowhere to escape such as to increase a likelihood of the package structure being damaged when the lower dam 82 of the side dam 8 collapses during the reflow process. Similarly, the first opening OP1 can provide an escape path for gas in the second accommodating space SP2, and will not cause the gas to have nowhere to escape such as to damage the package structure when the upper dam 81 of the side dam 8 collapses during the reflow process. However, it should be noted that the first opening OP1 is only for gas to enter and exit, and the flexible heat conductor 9 can still be confined in the second accommodation space SP2.

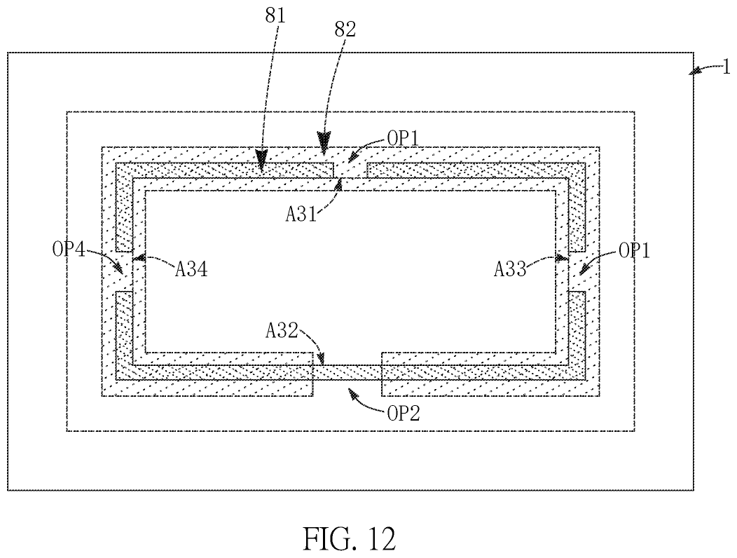

Reference is made to FIG. 12, which shows a schematic top view of another implementation of the side dam according to one embodiment of the present disclosure. As shown in FIG. 12, in the present embodiment, in a part of the side dam 8 corresponding to the first edge A31 of the rectangle, the upper dam 81 has a first opening OP1, and in a part of the side dam 8 corresponding to a second edge A32 of the rectangle, the lower dam 82 has a second opening OP2, and the first edge A31 is located opposite to the second edge A32. In addition, in a part of the side dam 8 corresponding to a third edge A33 of the rectangle, the upper dam 81 has a third opening OP3, and in a part of the side dam 8 corresponding to a fourth edge A34 of the rectangle, the upper dam 81 has a fourth opening OP4.

Therefore, in the reflow process, the second opening OP2 can provide an escape path for gas at the bottom of the semiconductor package 2, and will not cause the gas to have nowhere to escape and damage the package structure when the lower dam 82 of the side dam 8 collapses during the reflow process. Similarly, the first opening OP1, the third opening OP3 and the fourth opening OP4 can provide an escape path for gas in the second accommodating space SP2, and will not cause the gas to have nowhere to escape and damage the package structure when the upper dam 81 of the side dam 8 collapses during the reflow process. However, it should be noted that the first opening OP1, the third opening OP3 and the fourth opening OP4 are only for gas to enter and exit, and the flexible heat conductor 9 can still be confined in the second accommodation space SP2.

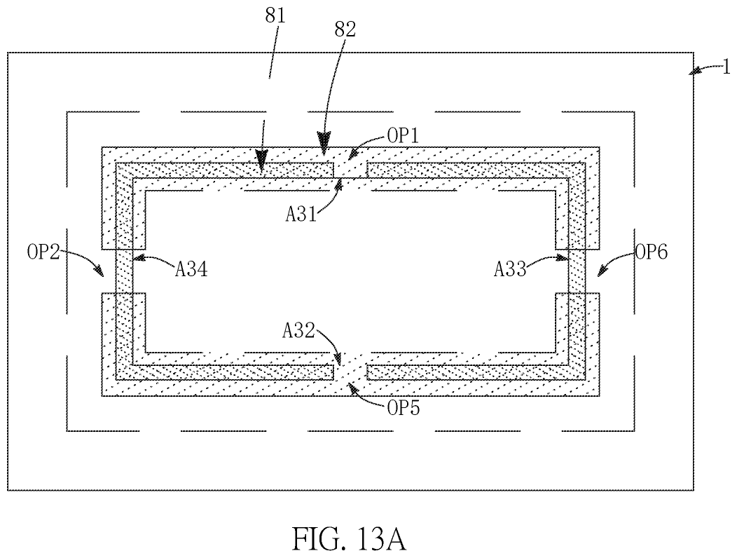

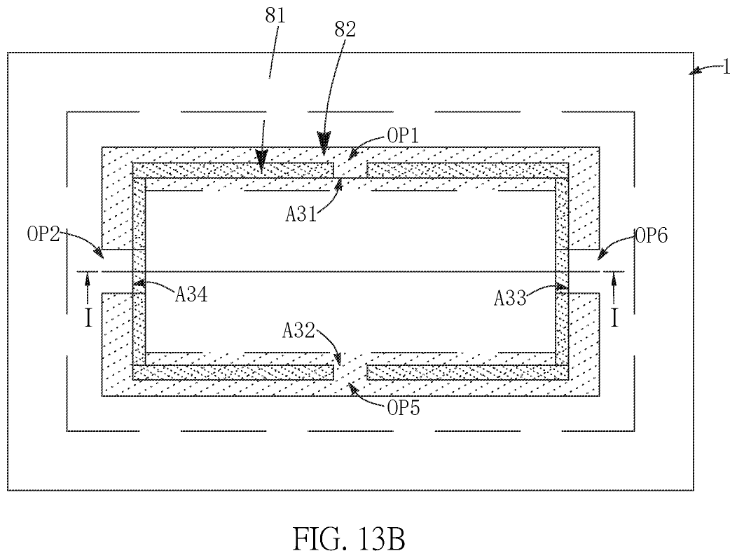

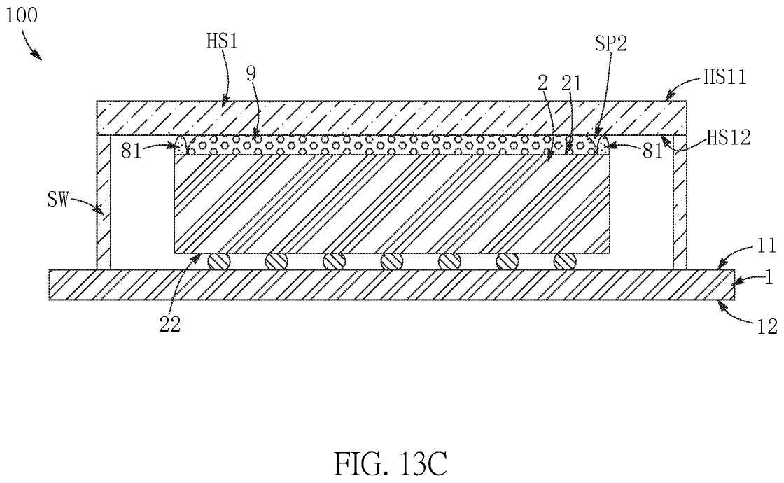

Reference is made to FIGS. 13A and 13B, which are schematic top views of yet another implementation of the side dam according to one embodiment of the present disclosure. As shown in FIGS. 13A and 13B, in the present embodiment, in a part of the side dam 8 corresponding to a first edge A31 of the rectangular, the upper dam 81 has a first opening OP1, and in a part of the side dam 8 corresponding to a second edge A32 of the rectangular, the lower dam 82 has a second opening OP2. In addition, in a part of the side dam 8 corresponding to a third edge A33 of the rectangle, the upper dam 81 has a fifth opening OP5, and in a part of the side dam 8 corresponding to a fourth edge A34 of the rectangle, the lower dam 82 has a sixth opening OP6. In this embodiment, the first edge A31 is located opposite to the third edge A33, and the second edge A32 is located opposite to the fourth edge A34.

However, there are two different arrangements for the upper dams 81 of the second edge A32 and the fourth edge A34. One of them is as shown in FIG. 13A, where the upper dams 81 of the second edge A32 and the fourth edge A34 are respectively disposed above the second opening OP2 and the sixth opening OP6 through arches similar to those of FIGS. 11A and 11B, and from a top view, where the upper dams 81 are located outside the edges of the third area A3 (that is, outside the side surface 23 of the semiconductor package 2). The other is as shown in FIG. 13B, where the upper dams 81 of the second edge A32 and the fourth edge A34 are disposed on the upper surface 21 and is located inside the edges of the third area A3 from a top view.

Therefore, reference can be further made to FIG. 13C, which is a schematic cross-sectional view taken along line I-I of FIG. 13B. As shown in FIG. 13C, the upper dam 81 is disposed on the upper surface 21, and jointly forms the second accommodating space SP2 with the first heat sink HS1 to confine the flexible heat conductor 9 therein.

Therefore, in the reflow process, the second opening OP2 and the sixth opening OP6 can provide an escape path for gas at the bottom of the semiconductor package 2, and will not cause the gas to have nowhere to escape such as to increase a likelihood of the package structure being damaged when the lower dam 82 of the side dam 8 collapses during the reflow process. Similarly, the first opening OP1 and the fifth opening OP5 can provide escape paths for gas in the second accommodating space SP2, and will not cause the gas to have nowhere to escape and damage the package structure when the upper dam 81 of the side dam 8 collapses during the reflow process. However, it should be noted that the first opening OP1 and the fifth opening OP5 are only for the gas to enter and exit, and the flexible heat conductor 9 can still be confined in the second accommodating space SP2.

### Beneficial Effects of the Embodiments

In conclusion, in the package structure and the method for fabricating the same, the fillet height and width of the side fill dispensing can be accurately controlled through the side fill dispensing structure and stacking or bridge dispensing method, while maintaining the heat dissipation efficiency between the semiconductor package and the heatsink or lid. The packaged chip components can be protected from solder joint cracking or open circuits caused by high and low temperature thermal deformation stress or falling, vibration and other mechanical stress, thereby improving product reliability.

Moreover, in the package structure and the method for fabricating the same, for specific products with additional surface mount technology (SMT) reflow and high heat dissipation requirements for chip packaged components, the flexible thermal conductive body can be confined above the semiconductor package by the accommodating space formed by the side dam, so as to avoid the package curling deformation pressing leakage of liquid heat dissipation grease in the subsequent SMT reflow process, resulting in insufficient heat dissipation interface or leakage of conductive liquid thermal adhesive and causing damage to the component.

Furthermore, in the package structure and the method for fabricating the same provided by the present disclosure, the need for traditional bottom or side dispensing processes such as module cleaning, baking, and surface conditioning can be eliminated, thereby significantly reducing overall production costs and the costs of traditional adhesive frames.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A package structure, comprising:
a substrate having a first board surface;
a semiconductor package having an upper surface, a lower surface, and a side surface between the upper surface and the lower surface, wherein the semiconductor package is disposed on the first board surface, and is electrically connected to the substrate through a plurality of pins disposed on the lower surface;
a side dam formed on the first board surface to surroundingly define a first accommodating space, wherein the semiconductor package is disposed in the first accommodating space and contacts the side dam, and the side dam has a height that is higher than a height of the upper surface;
a flexible heat conductor disposed on the upper surface;
a first heat sink disposed on the side dam and the flexible heat conductor, and being supported by the side dam;
wherein the first heat sink, the side dam and the semiconductor package jointly define a second accommodating space, and the flexible heat conductor is confined in the second accommodating space.

2. The package structure according to claim 1, wherein a first vertical projection is formed by projecting the semiconductor package onto the first board surface, and the side dam has a multilayer adhesive structure formed along at least a part among the side surface of the semiconductor package and a periphery of the first vertical projection.

3. The package structure according to claim 2, wherein the side dam has a dam cross section that is wider at a bottom and narrower at a top.

4. The package structure according to claim 1, wherein the first heat sink has a first surface and a second surface, the second surface contacts the side dam, a second vertical projection is formed by projecting the side dam onto the second surface, and an area of the second surface is greater than an area of the second vertical projection.

5. The package structure according to claim 4, further comprising a side wall disposed between the second surface and the first board surface, wherein the side wall and the first heat sink jointly form a package cover having a third accommodating space for accommodating the semiconductor package, the side dam and the flexible heat conductor.

6. The package structure according to claim 5, further comprising:
an interface heat conductor disposed on the first heat sink; and
a second heat sink disposed on the interface heat conductor.

7. The package structure according to claim 2, wherein the first vertical projection is a rectangle, and the side dam includes an upper dam higher than the upper surface and a lower dam lower than the upper surface,
wherein the upper dam has a first opening in a portion of the side dam corresponding to a first edge of the rectangle; and
wherein the lower dam has a second opening in a portion of the side dam corresponding to a second edge of the rectangle.

8. The package structure according to claim 7, wherein the first edge is located opposite to the second edge.

9. The package structure according to claim 8, wherein the upper dam has a third opening in a portion of the side dam corresponding to a third edge of the rectangle; and
wherein the upper dam has a fourth opening in a portion of the side dam corresponding to a fourth edge of the rectangle.

10. The package structure according to claim 7, wherein the upper dam has a fifth opening in a portion of the side dam corresponding to a third edge of the rectangle;
wherein the lower dam has a sixth opening in a portion of the side dam corresponding to a fourth edge of the rectangle; and
wherein the first edge is located opposite to the third edge, and the second edge is located opposite to the fourth edge.

11. A method for fabricating a package structure, the method comprising:
providing a substrate having a first board surface;
disposing a semiconductor package on the first board, and electrically connecting the semiconductor package to the substrate through a plurality of pins, wherein the semiconductor package has an upper surface, a lower surface, and a side surface between the upper surface and the lower surface, a first vertical projection is formed by projecting the semiconductor package onto the first board surface, and the plurality pins are disposed on the lower surface;
performing a dispensing process to form a side dam contacting the semiconductor package which surroundingly defines a first accommodating space for accommodating the semiconductor package, wherein a height of the side dam is higher than a height of the upper surface;
disposing a flexible heat conductor on the upper surface; and
disposing a first heat sink on the side dam and the flexible heat conductor, wherein the first heat sink is supported by the side dam, and the first heat sink, the side dam and the semiconductor package jointly define a second accommodating space, and the flexible heat conductor is confined in the second accommodating space.

12. The method according to claim 11, wherein in the dispensing process, a plurality of dispensing steps are sequentially performed to form a multilayer adhesive structure along at least a part among the side surface of the semiconductor package and a periphery of the first vertical projection, and the side dam is formed after a shape of the multilayer adhesive structure is completely formed.

13. The method according to claim 12, wherein the side dam has a dam cross section that is wider at a bottom and narrower at a top.

14. The method according to claim 11, wherein the first heat sink has a first surface and a second surface, the second surface contacts the side dam, a second vertical projection is formed by projecting the side dam onto the second surface, and an area of the second surface is greater than an area of the second vertical projection.

15. The method according to claim 14, further comprising disposing a side wall disposed between the second surface and the first board surface before disposing the first heat sink, so as to jointly form a package cover with the side wall and the first heat sink, wherein the package cover defines a third accommodating space for accommodating the semiconductor package, the side dam and the flexible heat conductor.

16. The method according to claim 15, further comprising:
disposing an interface heat conductor on the first heat sink; and
disposing a second heat sink on the interface heat conductor.
